(19) United States
(12) Patent Application Publication
(10) Pub. No.: US 2017/0236970 A1
(43) Pub. Date: Aug. 17, 2017

(54) METHOD FOR PRODUCING DOPING REGIONS IN A SEMICONDUCTOR LAYER OF A SEMICONDUCTOR COMPONENT

(71) Applicant: Fraunhofer-Gesellschaft zur Förderung der angewandten Forschung e.V., Munchen (DE)

(72) Inventors: Martin Hermle, Freiburg (DE); Christian Reichel, Berlin (DE); Jan Benick, Freiburg (DE); Ralph Muller, Freiburg (DE); Julian Schrof, Neuleinigen (DE)

(73) Assignee: Fraunhofer-Gesellschaft zur Förderung der angewandten Forschung e.V., Munchen (DE)

(21) Appl. No.: 15/502,671

(22) PCT Filed: Aug. 3, 2015
(86) PCT No.: PCT/EP2015/067842

§ 371 Date: Feb. 8, 2017

(30) Foreign Application Priority Data
Aug. 11, 2014 (DE) 10 2014 215 893.1

(51) Int. Cl. H01L 31/18; H01L 31/068

(52) U.S. Cl. CPC H01L 31/1804; H01L 31/1872; H01L 31/0682

(57) ABSTRACT

The invention relates to a method for producing doping regions in a semiconductor layer of a semiconductor component, wherein the method includes the following steps: A) implanting a first dopant of a first doping type into at least one implantation region in the semiconductor layer, which implantation region adjoins a first side of the semiconductor layer; B) applying a doping layer, which contains a second dopant of a second doping type, indirectly or directly at least to the first side of the semiconductor layer, wherein the first and the second doping type are opposite; C) by the effect of heat, simultaneously driving the second dopant from the doping layer into the semiconductor layer and performing one or more of the processes of at least partially activating the implanted dopant in the implantation region and/or performing at least partial recovery of crystal damage in the semiconductor layer, which crystal damage was produced by the implantation, and/or driving in the first dopant from the implantation region.

Furthermore, the application of doped glass layers comprising a dopant is known and the diffusion of the dopant out of the glass layer into the semiconductor layer. Additionally, masking methods are known in which a masking layer covers as a diffusion barrier only partial sections of the surface of the semiconductor layer and via diffusion from the gaseous phase here the formation of doping sections occurs in the semiconductor layer only at the areas not covered by the masking layer.

Further, methods are known in which a doping of a first doping type by a local introduction of a dopant of a second doping type in high concentrations is overcompensated. For example a method is known from US 2009/0227095 A1 in which first by way of diffusion from a gaseous phase a doping region of a first doping type is formed over the entire surface of one side of a semiconductor layer, and subsequently via ion implantation locally several doping regions are formed of a second doping type, which show higher concentrations in reference to the first doping type so that here overcompensation occurs in the above-mentioned local regions.

### SUMMARY

The invention is based on the objective to provide a cost-effective and robust method for producing at least one doping region of a first doping type and at least one doping region of a second doping type in a semiconductor layer.

This objective is attained in a method according to the invention. Advantageous embodiments of the method according to the invention are disclosed below.

The method according to the invention serves to produce doping regions in a semiconductor layer by at least one doping region of a first doping type being generated by introducing a dopant of the first doping type and at least one doping region of a second doping type by introducing a second dopant of the second doping type. The first and the second doping type are opposite.

The method comprises the following processing steps:

Implanting of the first dopant occurs in a processing step A in at least one implantation region into the semiconductor layer, with here the implantation region abutting to the first side of the semiconductor layer.

An application of a doping layer occurs in a processing step B, which comprises the second doping substance, at least onto the first side of the semiconductor layer. The doping layer can here be applied directly or indirectly, i.e. directly or by an interposition of additional intermediate layers onto the first side of the semiconductor layer, with preferably the doping layer being applied directly on the first side of the semiconductor layer.

The doping layer is therefore at least partially also applied in such regions of the first side of the semiconductor layer which abuts to the implementation region of the first dopant.

In a processing step C, by the application of heat, a simultaneous introduction occurs of the second dopant out of the doping layer into the semiconductor layer in order to produce at least one second doping region and one or more of the following procedures:

At least partially activating the implanted dopant in the implantation region and/or

At least partially curing crystal damages in the semiconductor layer caused by the implantation and/or

driving the first dopant out of the implantation region to produce a first doping region.

Here it is essential that in the processing step A the implantation region is embodied as a diffusion barrier for the second dopant, i.e. that the implantation region at least reduces the penetration of the second dopant.

The method according to the invention offers therefore a particularly simple and thus cost-effective and robust option to form the above-mentioned doping regions of the first and second doping type, because at least the implantation region in which the first dopant is implanted serves simultaneously to form the first doping region and acts as a diffusion barrier, in order to prevent any diffusion of the second dopant out of the doping layer into the implantation region.

This way particularly an alignment is omitted, which is required in methods of prior art, i.e. the local adjustment of two successive processing steps. Furthermore, in the processing step C several processes can occur simultaneously so that costly processing steps can be omitted. Furthermore, due to the fact that the implantation region acts as a diffusion barrier, this yields a decoupling of the doping profile of the first dopant and the second dopant: Based on the effect as a diffusion barrier of the implantation region it is particularly not required to yield any overcompensation as shown in US 2009/0227095 A1. The method according to the invention allows therefore a considerably higher degree of freedom in the selection of the doping concentration and the doping profile of both the first as well as the second dopant because no overcompensation of a dopant by another dopant is required.

In addition to these advantages the method according to the invention is cost-saving because compared to typical methods of prior art here fewer processing steps are necessary.

The designation diffusion barrier is here used in the sense of the common definition, i.e. that the penetration of the second dopant into the plantation region is considerably reduced in reference to non-implanted regions, preferably considerably reduced, particularly completely reduced (within the scope of the measuring scales common for doping profiles).

The at least partial activation of the implanted dopant in the implantation region represents here the integration of the implanted atoms in the grid of the semiconductor layer and thus their electric activation in the semiconductor. The scope of the present invention therefore includes here that only a portion of the implanted doping atoms are activated. Preferably at least 50%, further preferred at least 90% of the implanted doping atoms are activated. It is particularly preferred that all implanted doping atoms are activated.

An at least partial curing of the crystal damage generated by the implantation process represents here that by the introduction of heat the damages to the grid structure are corrected.

The implanted dopant shall be embodied in a manner electrically active for the semiconductor component. Preferably at least a partial activation of the implanted dopant occurs therefore in the processing step C.

Furthermore, in typical cases the implantation results in a damage of the semiconductor layer. In the processing step C therefore preferably at least a partial curing shall occur of crystal damages that were generated by the implantation, particularly in a manner advantageously combined with an at least partial activation of the implanted dopant.

The embodiment of the implantation region as a diffusion barrier for the second dopant occurs preferably by the first dopant being implanted with a concentration that is higher than the solubility limit of the first dopant in the semiconductor layer. Experiments of the applicant have shown that this way particularly for the application in photovoltaic solar cells and light diodes sufficiently effective as diffusion barriers can be yielded.

The embodiment of the implantation region occurs preferably such that the diffusion of the second dopant out of the diffusion layer is reduced by at least 90%, preferably at least 95%, particularly at least 99%. The effect as a diffusion barrier is improved when the doping concentration is increased in the implantation region.

Accordingly, preferably in the processing step A the dopant is implanted in the implantation region with a doping concentration exceeding 1×10²⁰ cm⁻³, preferably exceeding 5×10²⁰ cm⁻³, further preferred exceeding 1×10²¹ cm⁻³ in order to yield an advantageously effective diffusion barrier.

The scope of the invention includes that the first doping type represents the p-doping type and the second doping type the n-doping type.

The method is however particularly well suited to form doping regions in which the first doping type is the n-doping type and the second doping type the p-doping type; because in particular the method is advantageously applicable for semiconductor elements with the semiconductor layer showing a n-type base doping. Here, particularly the free selection of the p-type doping profile is advantageous for the embodiment of the semiconductor component. This particularly applies to photovoltaic solar cells.

In general, in this case the first dopant may represent a dopant from the group phosphorus, arsenic, or another material of Group V. Similarly, the second dopant may represent a dopant from the group boron, gallium, or another material of Group III.

In particular it is advantageous that the first dopant is phosphorus and/or the second dopant is boron. This is caused in that for the curing of implanted phosphorus only a temperature of approximately 850° C. is required and boron can be easily introduced with a diffusion process at the same temperature of 850° C. Additionally, both substances are well suited for the doping of silicon.

Preferably the doping layer is applied in the processing step B such that the doping layer overlaps the implantation region, particularly covers it completely; because as described above it is not necessary in the method according to the invention to consider any adjustment, for example between the doping layer and the implantation region. For example, particularly the doping layer can be applied completely covering the implantation region. In a particularly advantageous, procedurally economic fashion here in the processing step B the doping layer can be applied indirectly or preferably directly over the entire area of the first surface of the semiconductor layer.

The method according to the invention allows a plurality of variations with regards to the embodiment and arrangement of the implantation region:

In an advantageous embodiment the implantation region extends only over a partial area of the first side of the semiconductor layer. This way at the first side of the semiconductor layer a local doping region of the first doping type is generated in the semiconductor layer via the first dopant. It is particularly advantageous to form several implantation regions at the first side of the semiconductor layer, which are locally spaced apart from each other such that accordingly several spaced apart doping regions of the first doping type are formed. This particularly applies for an embodiment of components that are unilaterally contacted, such as unilaterally contacted solar cells in which both the p-doped as well as the n-doped contacting occurs from one side, typically the back of the solar cell facing away from the incident radiation utilized.

Here it is particularly advantageous that the doping layer is applied indirectly or preferably directly on the first side of the semiconductor layer and covers it completely. This way in a simple manner a doping scheme is generated at the first side of the semiconductor layer in which at least one implantation region forms a doping region of the first doping type and in all other regions a doping region forms of the second doping type.

In particular when a plurality of implantation regions are provided, like the above-described spatially distanced ones, here the formation of several spatially separated doping regions of the first doping type are yielded in an alternating doping pattern at the first side of the semiconductor layer in a simple fashion, in which respectively a doping region of the first doping type and a doping region of the second doping type alternate over the first side of the semiconductor layer.

If the implantation region extends only over a partial section of the first side of the semiconductor layer advantageously in the processing step A the implantation occurs via a mask. Any local implantation via a mask is known per se and represents a simple and cost-effective option to generate one or more local implantation regions.

The mask is formed in a manner such that it is impenetrable for the first dopant and can be arranged in a fashion known per se directly or indirectly on the semiconductor layer, in particular embodied as a paint mask. However the mask can also be applied by a printing process, for example by an inkjet or screen printing process.

It is particularly advantageous to use a shadow mask, which is arranged at a distance from the semiconductor layer between the semiconductor layer and the ion radiation source for the first dopant. This way a simple method results because no mask needs to be applied on the semiconductor layer and later again removed therefrom.

In another preferred embodiment the implantation region extends over the entire first side of the semiconductor layer. In this case here the entire first side of the semiconductor layer prevents any penetration of the second dopant or at least avoids it essentially.

Advantageously here the doping layer is applied in a manner respectively indirectly or preferably directly covering entirely the first side of the semiconductor layer and a second side of the semiconductor layer opposite the first side.

This leads to a simple procedure, because without the use of a shadow mask, for example, first an implantation region is formed over the entire surface of the first side and the nature of the typical implantation process includes that the implantation occurs only at one side of the semiconductor layer. The formation of the doping layer, for example from a gaseous phase, occurs however typically at both sides so that in a particularly simple, economically processed fashion in the processing step B the doping layer is applied at both sides and particularly over the entire surface respectively at the first and the second side of the semiconductor layer.

This way, in a simple fashion a doping is yielded via the first dopant at the first side and a doping via the second dopant at the second side. This preferred embodiment is therefore particularly suited for photovoltaic solar cells which show contacting structures at both sides for removing charge carriers, or also for light diodes, which respectively show contacting structures at both sides for supplying charge carriers.

The application of the doping layer in the processing step B and the introduction as well as the other process or processes in the processing step C can occur in situ in a processing chamber, particularly in a tube furnace, so that here a cost-effective method results.

In the processing step C preferably heating occurs to a temperature exceeding 700° C., preferably a temperature ranging from 700° C. to 1000° C., particularly preferred a temperature exceeding 800° C. This results in the advantage that at least a partial activation occurs in typical dopants.

When boron is used as the second dopant it is advantageous that the heating to a temperature exceeding 800° C., preferably to a temperature ranging from 850° C. to 950° C. occurs in order to yield suitable diffusion.

When using phosphorus as the first dopant it is advantageous for a heating process occurring to a temperature exceeding 800° C., preferably to a temperature ranging from 850° C. to 950° C. in order to yield suitable activation and diffusion.

The heating process occurs preferably for a period of at least 1 minute, preferably at least 10 minutes, particularly preferred at least 30 minutes, because in case of the heating period being too short here insufficient diffusion of the dopants occurs into the semiconductor layer.

After the processing step C, preferably indirectly or directly in a processing step D a metallic contacting structure is applied indirectly or directly onto the semiconductor layer. The metallic contacting layer is therefore in contact with the semiconductor layer at least over a portion of its surface in order to form an electric contact. This way the contacting structures for feeding or removing charge carriers are formed in a simple fashion known per se.

In another preferred embodiment, after the processing step C, a dielectric layer is applied on the semiconductor layer in a processing step D′ and a metallic contacting layer is applied on the dielectric layer in a processing step D″ in order to form a metallic contacting structure. The metallic contacting is embodied such that sectionally here the metallic layer is penetrated by the dielectric layer. This is preferably yielded such that the dielectric layer is locally opened at several sections between the processing step D′ and the processing step D″. At these sections of the local opening the contacting layer therefore penetrates the dielectric layer to form an electric contact to the semiconductor layer. The scope of the invention also includes applying the dielectric layer over the entire surface without any openings, and applying thereon the metallic contacting layer, preferably over the entire surface, and via the effect of local heating generated by a laser to generate local electric contacts in a LFC-method, such as described for example in DE 10046170 A1.

It is particularly advantageous that the dielectric layer covers the semiconductor layer indirectly or preferably directly over the entire surface of at least the first side.

Typical semiconductor components, particularly photovoltaic solar cells or light diodes, are based on silicon. The semiconductor layer is therefore preferably embodied as a silicon layer.

The scope of the invention includes that the semiconductor layer is applied indirectly or directly on a substrate, which may also represent a semiconductor or a non-semiconductor. It is also within the scope of the invention that the semiconductor layer is embodied as a semiconductor substrate, particularly as a semiconductor wafer, preferably as a silicon wafer.

In order to yield a particularly cost-effective method it is advantageous for the production of the semiconductor component to generate doping regions of the first doping type exclusively by ion implantation, particularly exclusively in the processing step A.

The method according to the invention is particularly suited for the production of a photovoltaic solar cell.

The designation “side of the semiconductor layer” is used in this application in the sense typical for semiconductor components, i.e. it refers to a large-area surface of the semiconductor layer. Typically in solar cells and light diodes the side subject to incident light and/or light emitted during use is called the front side and the opposite side is called the back side.

Advantageously, when using the method according to the invention for producing a photovoltaic solar cell the method is applied such that the first side is the back side of the solar cell.

In the processing step C the heat application occurs preferably by heating in a furnace, particularly at tube furnace. However, the thermal impact may also occur by an impingement with radiation, particularly laser radiation.

### BRIEF DESCRIPTION OF THE DRAWINGS

In the following additional preferred features and preferred embodiments are explained based on exemplary embodiments and figures. Here it shows:

FIGS. 1A-1C in the left column I), partial steps of a first exemplary embodiment of a method according to the invention in which an implantation region extends completely over a first side of a semiconductor layer and in the right column II), partial steps of a second exemplary embodiment of a method according to the invention, in which an implantation region extends only over a partial region of a first side of the semiconductor layer.

### DETAILED DESCRIPTION OF THE PREFERRED EMBODIMENTS

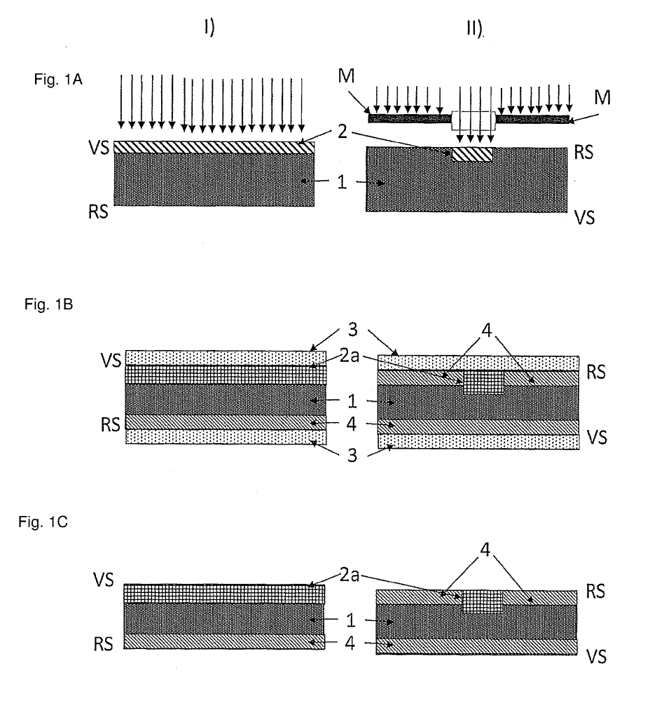

All illustrations in FIGS. 1A-1C show schematic cross-sections of details of the production process of a photovoltaic solar cell, not shown in a manner true to scale. In particular, the solar cell and/or its precursor continue to extend during the production process towards the right and the left and further details are not shown for reasons of clarity.

In FIGS. 1A-1C identical reference characters indicate the same elements or any elements with identical effects.

Sub-steps of a first exemplary embodiment of a method for generating doping regions in a semiconductor layer 1 are shown in the left column I) of FIGS. 1A-1C. The semiconductor layer 1 is embodied as a n-doped silicon wafer with a base doping of 0.5 to 10 Ohm cm. The method serves for the production of a photovoltaic solar cell.

A processing step A is shown in the detail of FIG. 1A in which an implanting occurs of a doping substance phosphorus, which therefore shows the n-doping type, in an implantation region 2 in the semiconductor layer 1. The implantation region 2 abuts at a first side of the semiconductor layer, which in the present case represents the front side VS of the semiconductor layer 1.

As discernible from FIG. 1A at I) the implantation region 2 is generated over the entire surface at the first side of the semiconductor layer 1.

The implantation occurs in a manner known per se at a few thousand electron-volt ion energy at a dose ranging from 1e14 to 1e16 cm⁻².

An application of a doping layer 3 occurs in a processing step B at both sides and over the entire surface directly on the semiconductor layer 1. The doping layer 3 therefore covers the entire surface of the front side VS, as well as the rear side RS of the semiconductor layer 1.

The doping layer comprises boron as the second dopant and thus has the p-doping type.

The doping layer 3 is embodied as a boron silicate glass known per se and is produced in a tube furnace process known from prior art. Such a process is also called a two-side coating of the semiconductor layer 1 with boron-silicate glass (BSG).

In this tube furnace process, at temperatures from 700° C. to 950° C., in the present case approximately 900° C., boron atoms are introduced from the BSG, i.e. the doping layer 3, into the semiconductor layer 1 for a period from 30 to 60 minutes via the application of heat in order to produce a second doping region 4. Thus, at the back side RS a boron doped region develops over the entire surface, which represents the second doping region 4. Simultaneously an activation occurs of the first dopant phosphorus, a curing process, which corrects crystal damages in the semiconductor layer 1 generated by the implantation of phosphorus as well as the introduction of the implanted dopant phosphorus for the formation of the first doping region 2a. The first, phosphorus-doped doping region 2a extends therefore over the entire surface at the front side VS of the semiconductor layer 1. Furthermore, by the temperature treatment here a curing process occurs of the implantation region 2. During the implantation process here glass is formed in the implantation region 2, at least partially. In the above-mentioned temperature treatment however a recrystallization of the amorphous region occurs to a crystalline region, so that furthermore potential defects are cured.

The result is shown in FIG. 1B at I).

Although the doping layer 3 also covers the implantation region 2 over the entire surface, here essentially no diffusion occurs of boron into the implantation region 2, though, because the implanted phosphorus acts in the implantation region as a diffusion barrier in reference to boron. The implantation region 2 is therefore embodied as a diffusion barrier for the second dopant boron. Here it is actually possible that minor quantities of boron penetrate into the implantation region 2, however it is essential that in the entire implantation region and the entire first doping region 2a formed such a low volume of the second dopant diffuses therein that the electric features are completely or at least essentially determined by the first dopant phosphorus.

Accordingly there is a considerable difference to methods of the prior art using overcompensation: The doping concentration of the second dopant boron in the second doping region 4 is considerably greater, typically by at least one dimension, than the doping concentration of the second dopant boron in the first doping region 2a, due to potentially minor diffusion from the doping layer 3 into the implantation region 2. With regards to the electronic features the implantation region 2 therefore acts as a (complete) diffusion barrier for the second dopant, regardless of minor quantities of the second dopant boron penetrating into the implantation region 2 on the atomic level.

Subsequently, the boron-silicate glass is removed with hydrofluoric acid. The result is shown in FIG. 1C at I). Here, in a simple fashion, a phosphorus-doped first doping region 2a was produced at the front side VS of the semiconductor layer 1 and a boron-doped second doping region 4 at the back side RS of the semiconductor layer 1.

The front side VS represents here the side facing the irradiation when used as a solar cell.

A second exemplary embodiment is shown at the right column of FIGS. 1A-1C at II), in which at the back side RS of the semiconductor layer 1 several local first doping regions 2a are produced. For reasons of clarity only one local first doping region 2a is shown.

In a processing step A, a local implanting occurs of the first dopant phosphorus into the implantation region 2. The local implanting process occurs such that via the shadow mask M the implantation of the first dopant is prevented over partial areas. This is shown in FIG. 1A at II).

Accordingly, after the processing step A, several spatially spaced apart local implantation regions 2 are given at the back side RS of the semiconductor layer 1. For this purpose the shadow mask M shows accordingly several openings, which for reasons of clarity are not shown in FIGS. 1A-C as explained above.

In a processing step B, as already described in the first exemplary embodiment, a coating of both sides occurs of the semiconductor layer 1 with the doping layer 3, which is formed as a boron-silicate glass and thus comprises boron as the second dopant.

Subsequently, in a processing step C, similar to the way described for the first exemplary embodiment, simultaneously the activation of the first dopant occurs, the introduction of the second dopant out of the doping layer 3 into the semiconductor layer 1, the introduction of the first dopant out of the implantation region 2 to generate the first doping region 2a, and the curing of defects in the implantation region 2.

An essential difference to the first exemplary embodiment is here that due to the local embodiment of the implantation region 2, which therefore fails to completely cover the back side RS of the semiconductor layer 1, at the back RS of the semiconductor layer 1 in an alternating fashion second doping regions 4 and first doping regions 2a are present. However, at the front side VS of the semiconductor layer 1, over the entire surface, a second doping region 4 is formed, which is therefore also boron-doped.

The result is shown in FIG. 1B at II).

Subsequently, as described above, the boron-silicate glass is removed. The result is shown in FIG. 1C at II).

Therefore, in a simple fashion via the second exemplary embodiment of the method according to the invention the production of a photovoltaic solar cell is provided, which at the front side VS has over the entire surface a boron-doped doping region and at the back side alternating boron-doped and phosphorus-doped doping regions. This way, on the one side in a simple fashion, the boron-doped second doping region 4 can be contacted at the back side via a metal contacting structure, and on the other side, the phosphorus-doped first doping region 2a can be contacted via another metal contacting structure such that a photovoltaic solar cell is generated contacted at the back side. The boron-doping formed at the front side VS can here serve as a so-called “floating emitter” at the front side, without any separate electric contacting, in order to allow the use of other passivation layers and/or to improve the lateral one of minority charge carriers.

Additionally, (not shown) an electrically conductive connection of the doping region 4 at the front VS can occur to the doping region 4 at the back side RS, for example by forming a EWT-solar cell, by providing another local boron-diffusion which penetrates the semiconductor layer perpendicularly in reference to the front and thus connects the front doping region 4 to the rear doping region 4, and/or by the formation of a MWT-solar cell by providing an additional metallization of the doping region 4, which is guided through the semiconductor layer 1 to a rear contacting.

1. A method for generating doping regions in a semiconductor layer (1) of a semiconductor component,
comprising generating at least one doping region of a first doping type by introducing a first dopant of the first doping type and generating at least one doping region of the second doping type by introducing a second dopant of the second doping type, with the first and the second doping type being opposite,
the method further comprises:
A implanting the first dopant into at least one implantation region in the semiconductor layer, with the implantation region abutting to a first side of the semiconductor layer (1),
B applying a doping layer which comprises the second dopant indirectly or directly at least on the first side of the semiconductor layer (1);
C driving the second dopant by the effect of heat out of the doping layer (3) into the semiconductor layer (1) for generating at least the second doping region and carrying out one or more of the processes of
at least partially activating the implanted dopant in the implantation region,
at least partially curing crystal damage generated in the semiconductor layer (1) by the implantation process, or
driving the first dopant out of the implantation region to generate the first doping region,
with the processing step A of the implantation region providing a diffusion barrier for the second dopant.

2. The method according to claim 1, wherein the implantation region is embodied as the diffusion barrier for the second dopant, in which the first dopant is implanted with a concentration which is greater than a solubility limit of the first dopant in the semiconductor layer (1).

3. The method according to claim 1, wherein in the processing step A the dopant in the implantation region is implanted with a doping concentration exceeding 1×10²⁰ cm⁻³.

4. The method according to claim 1, wherein the first doping type is of an n-doping type and the second doping type is of a p-doping type.

5. The method according to claim 1, wherein in the processing step B the doping layer (3) overlaps the implantation region.

6. The method according to claim 1, wherein the implantation region only extends over a portion of the first side of the semiconductor layer (1).

7. The method according to claim 6, wherein in the processing step A the implantation occurs via a mask.

8. The method according to claim 1, wherein the implantation region extends over an entire first side of the semiconductor layer (1).

9. The method according to claim 1, wherein the processing steps B and C are performed in-situ in a processing chamber.

10. The method according to claim 1, wherein in the processing step C, heating occurs to a temperature exceeding 700° C.

11. The method according to claim 1, further comprising after the processing step C in a processing step D directly applying a metallic contacting layer is directly applied on the semiconductor layer (1).

12. The method according to claim 1, further comprising after the processing step C, in a processing step D′ applying a dielectric layer on the semiconductor layer (1), and in a processing step D″ applying a metallic contacting layer on the dielectric layer.

13. The method according to claim 1, wherein the semiconductor layer (1) is a silicon layer.

14. The method according to claim 1, wherein a generation of the doping region of the first doping type occurs exclusively via ion implantation in the processing step A.

15. The method according to claim 1, further comprising that producing a photovoltaic solar cell using the method.
